(19) United States
(12) Patent Application Publication
(10) Pub. No.: US 2026/0144096 A1
(43) Pub. Date: May 21, 2026

(54) FINER VIA PITCH FOR THICKER CORE SUBSTRATE

(71) Applicant: QUALCOMM Incorporated, San Diego, CA (US)

(72) Inventors: Jaehyun YEON, San Diego, CA (US); Yeoil PARK, Sejong (KR); Hyunchul CHO, Suwon (KR); Michelle Yejin KIM, Carlsbad, CA (US); Kun FANG, San Diego, CA (US)

(21) Appl. No.: 18/951,335

(22) Filed: Nov. 18, 2024

(51) Int. Cl. H01L 23/498; H01L 21/768; H01L 23/00

(52) U.S. Cl. CPC H10W 70/635; H10W 20/062; H10W 20/089; H10W 70/65; H10W 72/921; H10W 72/923; H10W 72/942

(57) ABSTRACT

Disclosed are semiconductor packages. A semiconductor package may include a core substrate and one or more vias within the core substrate. The core substrate may include a base core and an upper core. The core substrate may also include a base core. The base core may be relatively thin so that laser drilling may be used and filled with conductive material. In this way, tight dimensions—e.g., small via width, small via pad width, and/or tight via pitches—may be achieved. Also by supplementing the base core with the upper and/or lower cores, an overall thick core may be achieved to enhance mechanical stability.

### BACKGROUND OF THE DISCLOSURE

### 1. Field of the Disclosure

This disclosure relates generally to die packages or modules, and more specifically, but not exclusively, to semiconductor packages/modules that include finer via pitch for thicker core substrates and fabrication techniques thereof.

### 2. Description of the Related Art

In semiconductor packages, cores are used for signal distribution and for mechanical stability. For example, in flip chip ball grid array (FCBGA) applications, thicker cores are desirable for warpage control. However, for thick cores, mechanical drilling is performed, which increases the via pitch. For better electrical performance, tight via pitches are needed. To get tighter via pitches, laser drilling is used. Unfortunately, laser drilling only works with thin cores. Accordingly, there is a need for systems, apparatus, and methods that overcome the deficiencies of conventional semiconductor packages including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary semiconductor package is disclosed. The semiconductor package may comprise a core substrate. The core substrate may comprise a base core and an upper core on an upper surface of the base core. The semiconductor package may also comprise one or more vias within the core substrate extending an entire height of the core substrate The one or more vias may comprise one or more base vias in the base core and one or more upper vias in the upper core. The one or more base vias may correspond to the one or more upper vias. The one or more base vias may be electrically coupled to the corresponding one or more upper vias. An upper surface of at least one base via may be in contact with a lower surface of at least one upper via. A width of the upper surface of the at least one base via may be wider than a width of the lower surface of the at least one upper via.

A method of fabricating a semiconductor package is disclosed. The method may comprise providing a core substrate. The core substrate may comprise a base core and an upper core on an upper surface of the base core. The method may also comprise forming one or more vias within the core substrate extending an entire height of the core substrate The one or more vias may comprise one or more base vias in the base core and one or more upper vias in the upper core. The one or more base vias may correspond to the one or more upper vias. The one or more base vias may be electrically coupled to the corresponding one or more upper vias. An upper surface of at least one base via may be in contact with a lower surface of at least one upper via. A width of the upper surface of the at least one base via may be wider than a width of the lower surface of the at least one upper via.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 illustrates a cross section of a conventional semiconductor package.

FIG. 2A illustrates a cross section of a semiconductor package in accordance with one or more aspects of the disclosure.

FIG. 2B illustrates an enlarged view of the semiconductor package of FIG. 2A.

FIGS. 3A-3I illustrate examples of stages of fabricating a semiconductor package in accordance with one or more aspects of the disclosure.

FIGS. 4-6 illustrate flow charts of example methods of manufacturing a semiconductor package in accordance with one or more aspects of the disclosure.

FIG. 7 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are semiconductor packages and methods for fabricating the same. In an aspect, the semiconductor package may comprise a core substrate. The core substrate may comprise a base core and an upper core on an upper surface of the base core. The semiconductor package may also comprise one or more vias within the core substrate extending an entire height of the core substrate. The one or more vias may comprise one or more base vias in the base core and one or more upper vias in the upper core. The one or more base vias may correspond to the one or more upper vias. The one or more base vias may be electrically coupled to the corresponding one or more upper vias. An upper surface of at least one base via may be in contact with a lower surface of at least one upper via. A width of the upper surface of the at least one base via may be wider than a width of the lower surface of the at least one upper via. In this way, electrical performance may be enhanced by providing tight via pitches, small via widths, and small pad widths. At the same time, mechanical stability may be enhanced.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

As indicated above, in semiconductor packages, cores are used for signal distribution and for mechanical stability. In flip chip ball grid array (FCBGA) applications, thicker cores are desirable for warpage control. However, for thick cores, mechanical drilling is performed, which increases the via pitch. For example, for over 300 μm thickness core, tenting process can be only applied for drill and lithography. For better electrical performance, tight via pitches are needed. To get tighter via pitches, laser drilling is used. Unfortunately, laser drilling only works with thin cores.

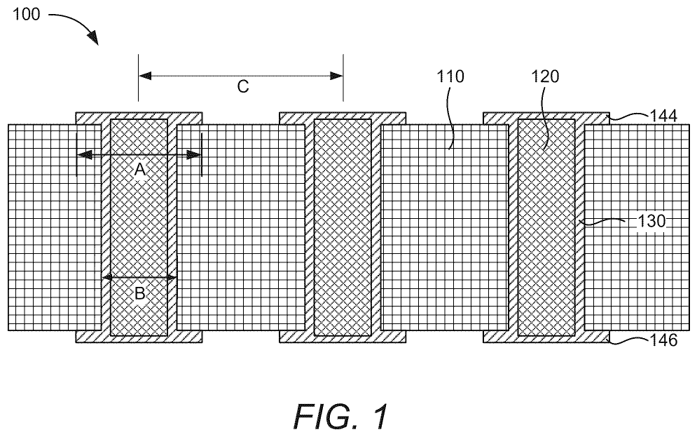

FIG. 1 illustrates a cross section of a conventional semiconductor package 100, which includes a core 110 and a plurality of vias 130 within the core 110. A plurality of plugs 120 fill the center portions of the corresponding plurality of vias 130. A plurality of upper pads 144 are formed on the upper surface of the core 110 and are in contact with the corresponding plurality of vias 130. Also, a plurality of lower pads 146 are formed on the lower surface of the core 110 and are in contact with the corresponding plurality of vias 130.

The core 110 is thick (e.g., 400 μm or greater thickness). As indicated, thick core helps with maintaining mechanical integrity. For example, thick core minimizes or even prevents warpage. However, with thick cores, mechanical drilling and tenting are used to form holes in the core 110, which are then filled with conductive materials to form the vias 130. Unfortunately, tight dimensions necessary for good electrical performance are difficult to achieve. In FIG. 1, three dimensions—A, B, C—are indicated. A represents the pad width, B represents the via width, and C represents the via pitch (center-to-center distance between adjacent vias 130. For the conventional thick core 110, A can be 120 μm or more, B can be 250 μm or more, and C can be 325 μm or more.

To address these and other issues of the conventional semiconductor package, it is proposed to build a core substrate that utilized a thinner core and laminate on top and bottom of the thinner core. The thinner core can be laser drilled enabling much tighter dimensions of vias and pads (e.g., pad width, via width, via pitch, etc.). The laminate layers can enhance the mechanical integrity. The resulting core substrate can be relatively thick (e.g., 400 μm or greater).

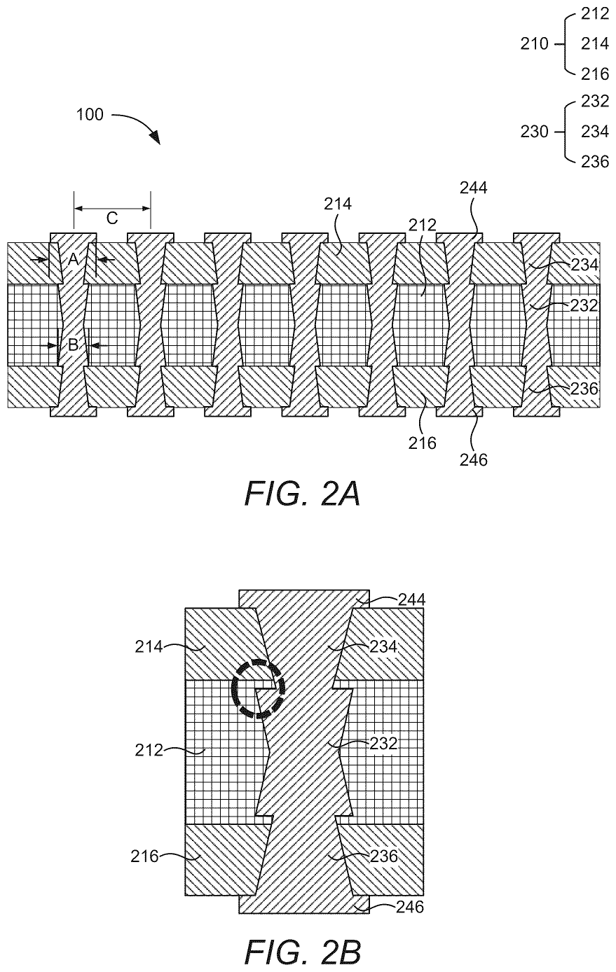

FIG. 2A illustrates a cross section of a semiconductor package 200 in accordance with one or more aspects of the disclosure. The semiconductor package 200 may include a core substrate 210, which may comprise a base core 212 and an upper core 214 on an upper surface of the base core 212. In an aspect, the upper core 214 may be formed from a pregreg (PPG) material, a carbon fiber (GCF) material, or both. The base and upper core 212, 214 may be formed from dielectric materials. Before proceeding further, it should be noted that terms and phrases such as “upper”, “lower”, “top”, “bottom”, “left”, “right”, etc. are merely used for convenience. Unless specifically indicated otherwise, these terms should NOT be taken to be limiting as requiring specific orientation and/or direction.

Optionally, the core substrate 210 may also include a lower core 216 on a lower surface of the base core 212. That is, the substrate package 200 may be double-sided, i.e., may be mirrored above and below the base core 212. In an aspect, the lower core 216 may be formed from a PPG material, a GCF material, or both. Generally, the lower core 216 may be formed from dielectric materials. For the remainder of this disclosure, a double-sided semiconductor package 200 will be described, with the understanding that single-sided semiconductor packages (above or below the base core 212) are contemplated and straightforward to arrive.

The semiconductor package 200 may also include one or more vias 230 within the core substrate 210. The one or more vias 230 may extend an entire height of the core substrate 210, and may comprise one or more base vias 232 in the base core 212 and one or more upper vias 234 in the upper core 214. The one or more base vias 232 may correspond to the one or more upper vias 234. The one or more base vias 232 may be electrically coupled to the corresponding one or more upper vias 234. For example, the one or more base vias 232 may be in direct contact with the corresponding one or more upper vias 234. Indeed, the base vias 232 and the upper vias 234 may be formed from a same conducive metal such as copper (Cu).

In an aspect, an upper surface of at least one base via 232 may be in contact with a lower surface of corresponding at least one upper via 234. As seen, a width of the upper surface of the at least one base via 232 may be wider than a width of the lower surface of the at least one upper via 234. FIG. 2B illustrates an enlarged view of a portion (see circled dashed portion) of the semiconductor package of FIG. 2A. As seen in FIG. 2B, the upper surface of the at least one base via 232 may be below the upper surface of the base core 212.

Referring back to FIG. 2A, when the semiconductor package 200 is double-sided, the one or more vias 230 may further include one or more lower vias 236 in the lower core 216. The one or more base vias 232 may also correspond to the one or more lower vias 236. The one or more base vias 232 may be electrically coupled to the corresponding one or more lower vias 236. For example, the one or more base vias 232 may be in direct contact with the corresponding one or more lower vias 236. The base vias 232 and the lower vias 236 may be formed from a same conducive metal such as Cu.

In an aspect, a lower surface of the at least one base via 232 may be in contact with an upper surface of corresponding at least one lower via 236. A width of the lower surface of the at least one base via 232 may be wider than a width of the upper surface of the at least one lower via 236. Also as seen in FIG. 2B, the lower surface of the at least one base via 232 may be above the lower surface of the base core 212.

Referring back to FIG. 2A, the semiconductor package 200 may further include one or more upper pads 244 formed on an upper surface of the upper core 214 and on upper surfaces of the one or more upper vias 234. The one or more upper pads 244 may correspond to the one or more upper vias 234. The one or more upper pads 244 may be electrically coupled to the corresponding one or more upper vias 234. For example, the upper pads 244 and the upper vias 234 may be in contact with each other. The one or more upper pads 244 may be integrally formed with the corresponding one or more upper vias 234. That is, the upper pads 244 and the upper vias may be formed as a single unit in one process.

For double-sided structure, the semiconductor package 200 may include one or more lower pads 246 formed on a lower surface of the lower core 216 and on lower surfaces of the one or more lower vias 236. The one or more lower pads 246 may correspond to the one or more lower vias 236. The one or more lower pads 246 may be electrically coupled to the corresponding one or more lower vias 236. For example, the lower pads 246 and the lower vias 236 may be in contact with each other. The one or more lower pads 246 may be integrally formed with the corresponding one or more lower vias 236.

Note that the via and pad dimensions of the semiconductor package 200 are much tighter relative to the conventional semiconductor package 100. For example, dimension B representing a base via width (i.e., width of the one or more base vias 232) of the proposed semiconductor package 200 may be 70 μm or less. Also, dimension A representing upper pad width (width of the one or more upper pads 244) may be 105 μm or less. Note that dimension A may also apply to lower pad width (width of the one or more lower pads 246). Dimension C representing a via pitch (center-to-center distance between two adjacent vias 230) may be 130μm or less.

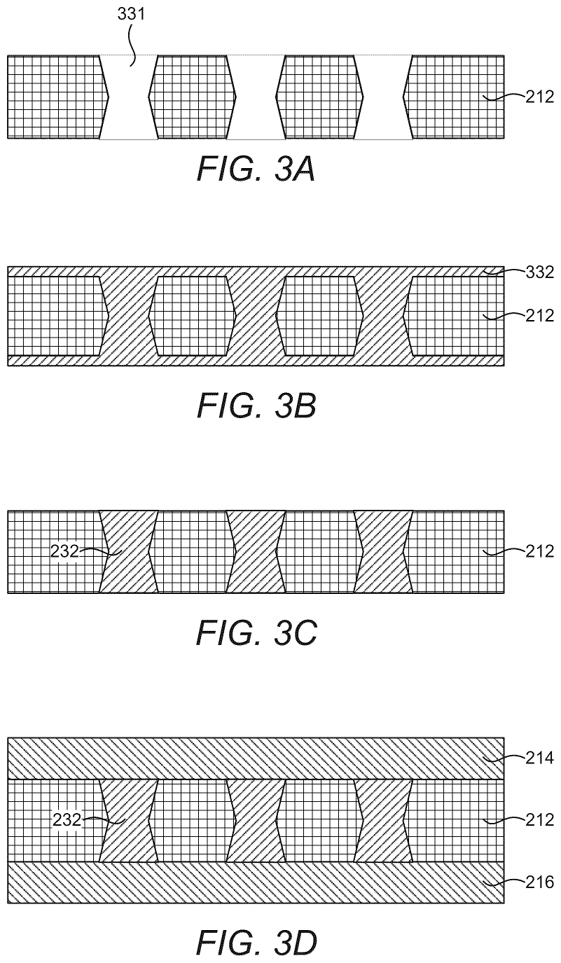

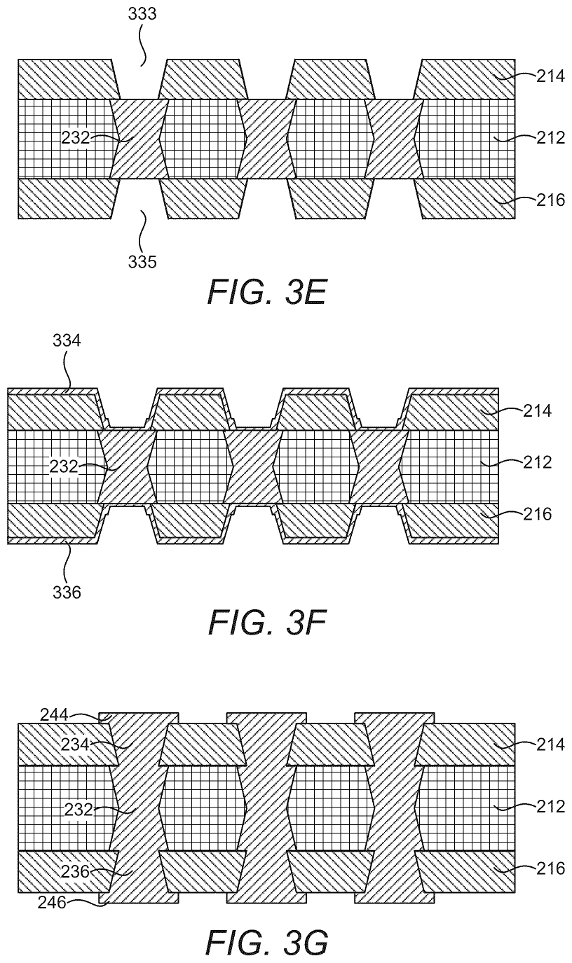

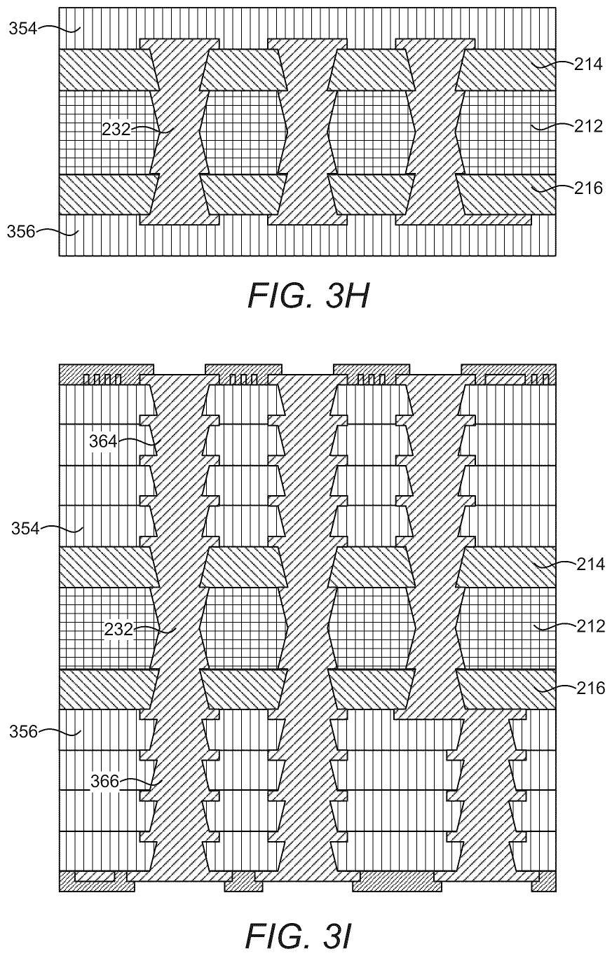

As will be seen in FIG. 3I below, the semiconductor package 200 may include one or more upper laminate layers 354 stacked on and above the upper core 214. For example, the one or more upper laminate layers 354 may be formed from Ajinomoto build-up film (ABF). The one or more upper laminate layers 354 may be formed from dielectric materials. The semiconductor package 200 may further include one or more upper metal layers 364 (e.g., Cu) formed in the one or more upper laminate layers 354. The one or more upper metal layers 364 may distribute electrical signals to and/or from the one or more upper vias 234.

Also as will be seen in FIG. 3I below, the semiconductor package 200 may include one or more lower laminate layers 356 stacked on and below the lower core 216. In an aspect, the one or more lower laminate layers 356 may be formed from dielectric materials including ABJ materials. The semiconductor package 200 may further include one or more lower metal layers 366 (e.g., Cu) formed in the one or more lower laminate layers 356. The one or more lower metal layers 366 may distribute electrical signals to and/or from the one or more lower vias 236.

FIGS. 3A-3I illustrate examples of stages of fabricating a semiconductor package—such as the semiconductor package 200—in accordance with one or more aspects of the disclosure. In this instance, stages of fabricating a double-sided structure are illustrated. But as indicated above, it is relatively straightforward to modify the process to fabricate a single-sided structure.

FIG. 3A illustrates a stage in which the base core 212 may be laser drilled to form one or more base via holes 331. In an aspect, the base via holes 331 may extend the entire height of the base core 212. For example, both top and bottom sides of the base core 212 may be subject to the laser drilling.

FIG. 3B illustrates a stage in which the base core 212 may be plated with a base conductive material 332 to fill the one or more base via holes 331. The base conductive material 332 may be a metal such as Cu. The plating may leave the base conductive material 332 on one or both of the upper and lower surfaces of the base core 212.

FIG. 3C illustrates a stage in which etching may take place to entirely remove the base conductive material 332 from the upper surface of the base core 212. Alternatively or in addition thereto, etching may entirely remove the base conductive material 332 from the lower surface of the base core 212. As a result, the base vias 232 may be formed. To ensure that the base conductive material 332 is entirely removed from the surfaces, a slight over etching may take place, which may etch some top (bottom) portions of the base vias 232 so that the upper (lower) surfaces of the base vias 232 are below (above) the upper (lower) surface of the base core 212 (see FIG. 2B).

FIG. 3D illustrates a stage in which the upper core 214 may be provided on the upper surface of the base core 212. Alternatively or in addition thereto, the lower core 216 may be provided on the lower surface of the base core 212.

FIG. 3E illustrates a stage in which the upper core 214 may be laser drilled to form one or more upper via holes 333. The upper surfaces of the base vias 232 may be exposed by the upper via holes 333. Alternatively or in addition there to, the lower core 216 may be laser drilled to form one or more lower via holes 335. The lower surfaces of the base vias 232 may be exposed by the lower via holes 335.

FIG. 3F illustrates a stage in which the upper core 214 may be plated (e.g., electroless plating) with an upper conductive material 334 (e.g., Cu) to fill the one or more upper via holes 333. As a result, the one or more upper vias 234 may be formed. Alternatively or in addition thereto, the lower core 216 may be plated (e.g., electroless plating) with a lower conductive material 336 (e.g., Cu) to fill the one or more lower via holes 335. As a result, the one or more lower vias 236 may be formed.

FIG. 3G illustrates a stage in which lithography may be performed on the upper conductive material 334 to form the upper pads 244. Alternatively or in addition thereto, lithography may be performed on the lower conductive material 336 to form the lower pads 246.

FIG. 3H illustrates a stage in which an upper laminate layer 354 may be formed on upper surface of the upper core 214. Alternatively or in addition thereto, a lower laminate layer 356 may be formed on lower surface of the lower core 216.

FIG. 3I illustrates a stage in which any number of laminate layers and metal layers within the laminate layers may be formed. For example, one or more upper laminate layers 354 may be formed to stack on and above the upper core 214. One or more upper metal layers 364 may be formed in the one or more upper laminate layers 354. The one or more upper metal layers 364 may distribute electrical signals to and/or from the one or more upper vias 234. Alternatively or in addition thereto, one or more lower laminate layers 356 may be formed to stack on and below the lower core 216. One or more lower metal layers 366 may be formed in the one or more lower laminate layers 356. The one or more lower metal layers 366 may distribute electrical signals to and/or from the one or more lower vias 236. Note that when both the upper and lower metal laminate layers 354, 356 are present, it is NOT required that the number of such layers be equal. That is, the number of upper laminate layers 354 may be independent (same or different) from the number of lower laminate layers 356.

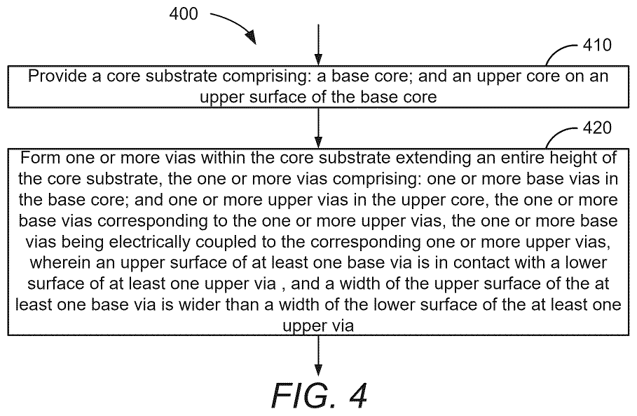

FIG. 4 illustrates a flow chart of an example method 400 of manufacturing a semiconductor package, such as the semiconductor package 200, in accordance with one or more aspects of the disclosure.

In block 410, core substrate 210 may be provided. The core substrate 210 may comprise a base core 212 and upper core 214 on upper surface of the base core 212.

In block 420, one or more vias 230 may be formed within the core substrate 210. The one or more vias 230 may extend an entire height of the core substrate 210. The one or more vias 230 may comprise one or more base vias 232 in the base core 212 and may also comprise one or more upper vias 234 in the upper core 214. The one or more base vias 232 may correspond to the one or more upper vias 234 and may be electrically coupled to the corresponding one or more upper vias 234. Upper surface of at least one base via 232 may be in contact with lower surface of at least one upper via 234. Also, width of the upper surface of the at least one base via 232 may be wider than a width of the lower surface of the at least one upper via 234.

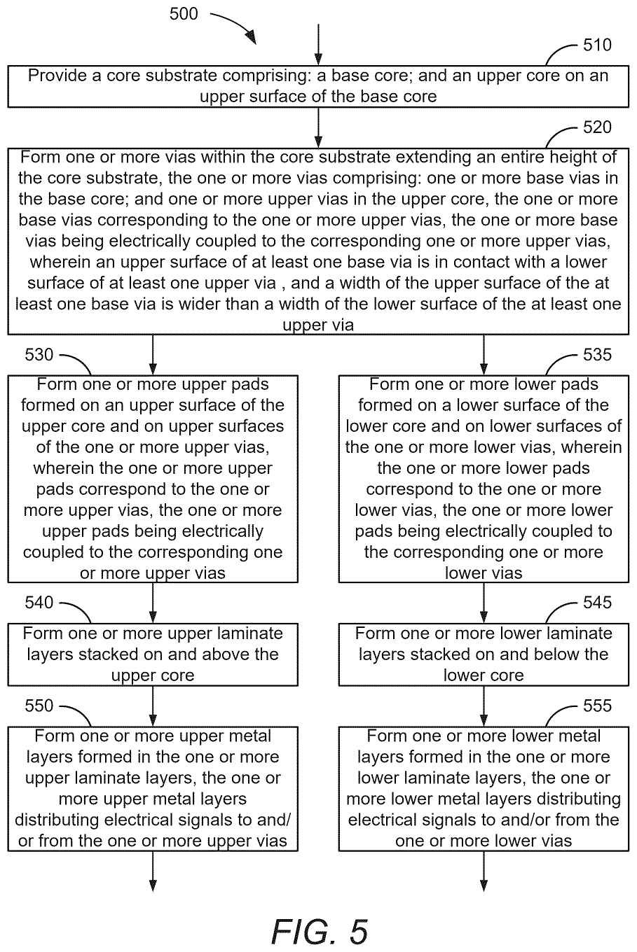

FIG. 5 illustrates a flow chart of an example method 500 of fabricating a semiconductor package, such as the semiconductor package 200 in accordance with at one or more aspects of the disclosure. FIG. 5 may be viewed as being more comprehensive than FIG. 4.

Block 510 may be similar to block 410. That is, in block 510, core substrate 210 may be provided. The core substrate 210 may comprise a base core 212 and upper core 214 on upper surface of the base core 212.

Block 520 may be similar to block 420. That is, in block 520, one or more vias 230 may be formed within the core substrate 210. The one or more vias 230 may extend an entire height of the core substrate 210. The one or more vias 230 may comprise one or more base vias 232 in the base core 212 and may also comprise one or more upper vias 234 in the upper core 214. The one or more base vias 232 may correspond to the one or more upper vias 234 and may be electrically coupled to the corresponding one or more upper vias 234. Upper surface of at least one base via 232 may be in contact with lower surface of at least one upper via 234. Also, width of the upper surface of the at least one base via 232 may be wider than a width of the lower surface of the at least one upper via 234.

In block 530, one or more upper pads 244 may be formed on an upper surface of the upper core 214 and on upper surfaces of the one or more upper vias 234. The one or more upper pads 244 may correspond to the one or more upper vias 234, and may be electrically coupled to the corresponding one or more upper vias 234.

In block 540, one or more upper laminate layers 354 may be formed. The one or more upper laminate layers 354 may be stacked on and above the upper core 214.

In block 550, one or more upper metal layers 364 may be formed in the one or more upper laminate layers 354. The one or more upper metal layers 364 may distribute electrical signals to and/or from the one or more upper vias 234.

When double-sided structure is manufactured, blocks 535, 545, and 555 may also be performed. In this instance, it may be assumed that the core substrate 210 further comprises the lower core 216 on the lower surface of the base core 212. Also, the one or more vias 230 may further comprise one or more lower vias 236 in the lower core 216.

In block 535, one or more lower pads 246 may be formed on a lower surface of the lower core 216 and on lower surfaces of the one or more lower vias 236. The one or more lower pads 246 may correspond to the one or more lower vias 236, and may be electrically coupled to the corresponding one or more lower vias 236.

In block 545, one or more lower laminate layers 356 may be formed. The one or more lower laminate layers 356 may be stacked on and below the lower core 216.

In block 555, one or more lower metal layers 366 may be formed in the one or more lower laminate layers 356. The one or more lower metal layers 366 may distribute electrical signals to and/or from the one or more lower vias 236.

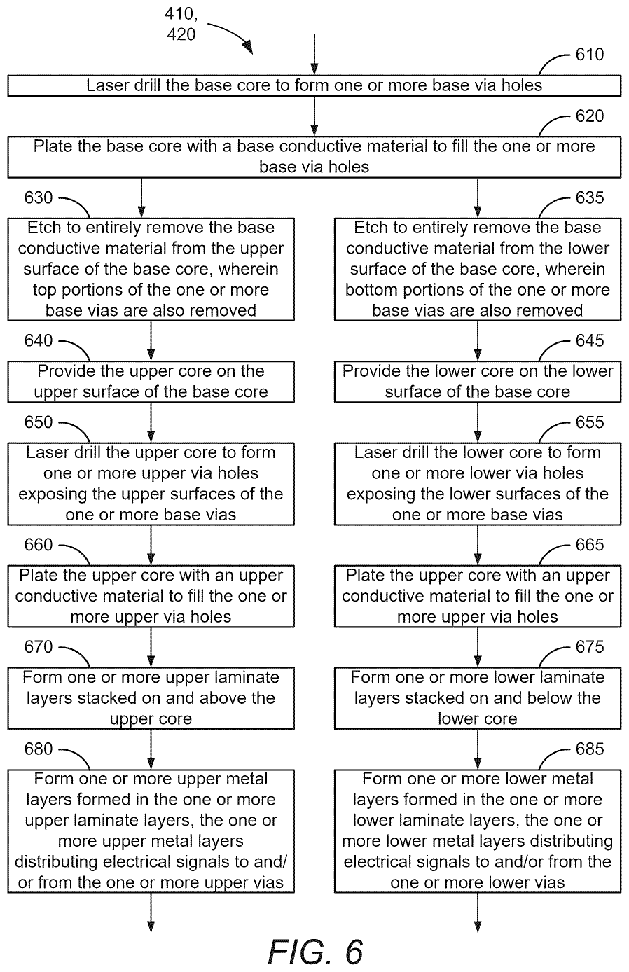

FIG. 6 illustrates a flow chart of an example process to perform blocks 410 and 420 of FIG. 4 (and hence blocks 510 and 520 of FIG. 5). In block 610, the base core 212 may be laser drilled to form one or more base via holes 331. Block 610 may correspond to the stage illustrated in FIG. 3A.

In block 620, the base core 212 may be plated with base conductive material 332 to fill the one or more base via holes 331. Block 620 may correspond to the stage illustrated in FIG. 3B.

In block 630, the base core 212 may be plated with base conductive material 332 to fill the one or more base via holes 331. The base conductive material 332 may be etched from the upper surface of the base core 212. The base conductive material 332 may be entirely removed from the upper surface of the base core 212. Top portions of the one or more base vias 232 may also be removed. Block 630 may correspond to the stage illustrated in FIG. 3C.

In block 640, the upper core 214 may be provided on the upper surface of the base core 212. Block 640 may correspond to the stage illustrated in FIG. 3D.

In block 650, the upper core 214 may be laser drilled to form one or more upper via holes 333. The one or more upper via holes 333 may expose upper surfaces of the one or more base vias 232. Block 650 may correspond to the stage illustrated in FIG. 3E.

In block 660, the upper core 214 may be plated (e.g., electroless plating) with upper conductive material 334 to fill the one or more upper via holes 333. Block 660 may correspond to the stage illustrated in FIG. 3F.

In block 670, one or more upper laminate layers 354 may be formed to be stacked on and above the upper core 214. Block 670 may correspond to the stages illustrated in FIGS. 3G and 3H.

In block 680, one or more upper metal layers 364 may be formed in the one or more upper laminate layers 354. The one or more upper metal layers 364 may distribute electrical signals to and/or from the one or more upper vias 234. Block 680 may correspond to the stage illustrated in FIG. 3H.

When double-sided structure is manufactured, blocks 635, 645, 655, 665, 675 and 685 may also be performed. In block 645, the lower core 216 may be provided on the lower surface of the base core 212. Block 645 may correspond to the stage illustrated in FIG. 3D.

In block 655, the lower core 216 may be laser drilled to form one or more lower via holes 335. The one or more lower via holes 335 may expose lower surfaces of the one or more base vias 232. Block 655 may correspond to the stage illustrated in FIG. 3E.

In block 665, the lower core 216 may be plated (e.g., electroless plating) with lower conductive material 336 to fill the one or more lower via holes 335. Block 665 may correspond to the stage illustrated in FIG. 3F.

In block 675, one or more lower laminate layers 356 may be formed to be stacked on and below the lower core 216. Block 675 may correspond to the stages illustrated in FIGS. 3G and 3H.

In block 685, one or more lower metal layers 366 may be formed in the one or more lower laminate layers 356. The one or more lower metal layers 366 may distribute electrical signals to and/or from the one or more lower vias 236. Block 685 may correspond to the stage illustrated in FIG. 3H.

The following should be noted regarding the flow indicated in FIGS. 4-6 . Unless otherwise indicated, the flow of blocks do not necessarily limit the ordering in which the blocks may be performed. In other words, the blocks may be performed in any order that is logical.

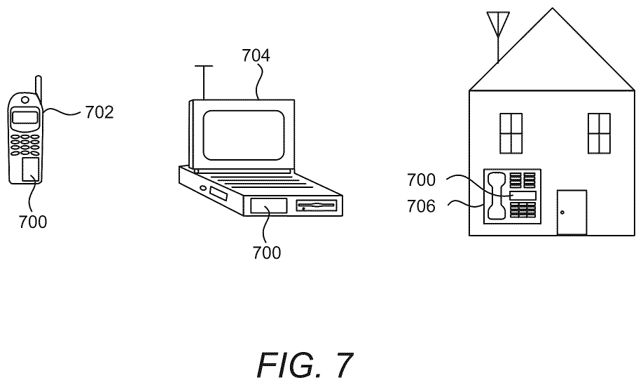

FIG. 7 illustrates various electronic devices 700 that may be integrated with any of the aforementioned semiconductor package in accordance with various aspects of the disclosure. For example, a mobile phone device 702, a laptop computer device 704, and a fixed location terminal device 706 may each be considered generally user equipment (UE) and may include one or more semiconductor packages (e.g., semiconductor package 200) as described herein. The devices 702, 704, 706 illustrated in FIG. 7 are merely exemplary. Other electronic devices may also include the die packages including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:
Clause 1: A semiconductor package, comprising: a core substrate comprising: a base core; and an upper core on an upper surface of the base core; and one or more vias within the core substrate extending an entire height of the core substrate, the one or more vias comprising: one or more base vias in the base core; and one or more upper vias in the upper core, the one or more base vias corresponding to the one or more upper vias, the one or more base vias being electrically coupled to the corresponding one or more upper vias, wherein an upper surface of at least one base via is in contact with a lower surface of at least one upper via, and a width of the upper surface of the at least one base via is wider than a width of the lower surface of the at least one upper via.
Clause 2: The semiconductor package of clause 1, wherein the upper surface of the at least one base via is below the upper surface of the base core.
Clause 3: The semiconductor package of any of clauses 1-2, wherein a base via width is 70 μm or less, the base via width being a width of the one or more base vias.
Clause 4: The semiconductor package of any of clauses 1-3, wherein a via pitch is 130 μm or less, the via pitch being a center-to-center distance between two adjacent vias.
Clause 5: The semiconductor package of any of clauses 1-4, one or more upper pads formed on an upper surface of the upper core and on upper surfaces of the one or more upper vias, wherein the one or more upper pads correspond to the one or more upper vias, the one or more upper pads being electrically coupled to the corresponding one or more upper vias.
Clause 6: The semiconductor package of clause 5, wherein an upper pad width is 105 μm or less, the upper pad width being a width of the one or more upper pads.
Clause 7: The semiconductor package of any of clauses 5-6, wherein the one or more upper pads are integrally formed with the corresponding one or more upper vias.
Clause 8: The semiconductor package of any of clauses 1-7, wherein the upper core is formed from a pregreg (PPG) material, a carbon fiber (GCF) material, or both.
Clause 9: The semiconductor package of any of clauses 1-8, further comprising:
   one or more upper laminate layers stacked on and above the upper core; and one or more upper metal layers formed in the one or more upper laminate layers, the one or more upper metal layers distributing electrical signals to and/or from the one or more upper vias.
Clause 10: The semiconductor package of any of clauses 1-9, wherein the core substrate further comprises a lower core on a lower surface of the base core, wherein the one or more vias further comprises one or more lower vias in the lower core, the one or more base vias also corresponding to the one or more lower vias, the one or more base vias being electrically coupled to the corresponding one or more lower vias, and wherein a lower surface of at least one base via is in contact with an upper surface of at least one lower via, and a width of the lower surface of the at least one base via is wider than a width of the upper surface of the at least one lower via.
Clause 11: The semiconductor package of clause 10, wherein the lower surface of the at least one base via is above the lower surface of the base core.
Clause 12: The semiconductor package of any of clauses 10-11, further comprising: one or more lower pads formed on a lower surface of the lower core and on lower surfaces of the one or more lower vias, wherein the one or more lower pads correspond to the one or more lower vias, the one or more lower pads being electrically coupled to the corresponding one or more lower vias.
Clause 13: The semiconductor package of any of clauses 10-12, further comprising: one or more lower laminate layers stacked on and below the lower core; and one or more lower metal layers formed in the one or more lower laminate layers, the one or more lower metal layers distributing electrical signals to and/or from the one or more lower vias.
Clause 14: The semiconductor package of any of clauses 1-13, wherein the semiconductor package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.
Clause 15: A method of fabricating a semiconductor package, the method comprising: providing a core substrate comprising: a base core; and an upper core on an upper surface of the base core; and forming one or more vias within the core substrate extending an entire height of the core substrate, the one or more vias comprising: one or more base vias in the base core; and one or more upper vias in the upper core, the one or more base vias corresponding to the one or more upper vias, the one or more base vias being electrically coupled to the corresponding one or more upper vias, wherein an upper surface of at least one base via is in contact with a lower surface of at least one upper via, and a width of the upper surface of the at least one base via is wider than a width of the lower surface of the at least one upper via.
Clause 16: The method of clause 15, wherein the upper surface of the at least one base via is below the upper surface of the base core.
Clause 17: The method of any of clauses 15-16, wherein a base via width is 70 μm or less, the base via width being a width of the one or more base vias.
Clause 18: The method of any of clauses 15-17, wherein a via pitch is 130μm or less, the via pitch being a center-to-center distance between two adjacent vias.
Clause 19: The method of any of clauses 15-18, forming one or more upper pads on an upper surface of the upper core and on upper surfaces of the one or more upper vias, wherein the one or more upper pads correspond to the one or more upper vias, the one or more upper pads being electrically coupled to the corresponding one or more upper vias.
Clause 20: The method of clause 19, wherein an upper pad width is 105 μm or less, the upper pad width being a width of the one or more upper pads.
Clause 21: The method of any of clauses 19-20, wherein the one or more upper pads are integrally formed with the corresponding one or more upper vias.
Clause 22: The method of any of clauses 15-21, wherein the upper core is formed from a pregreg (PPG) material, a carbon fiber (GCF) material, or both.
Clause 23: The method of any of clauses 15-22, further comprising: forming one or more upper laminate layers stacked on and above the upper core; and forming one or more upper metal layers in the one or more upper laminate layers, the one or more upper metal layers distributing electrical signals to and/or from the one or more upper vias.
Clause 24: The method of any of clauses 15-23, wherein the core substrate further comprises a lower core on a lower surface of the base core, wherein the one or more vias further comprises one or more lower vias in the lower core, the one or more base vias also corresponding to the one or more lower vias, the one or more base vias being electrically coupled to the corresponding one or more lower vias, and wherein a lower surface of at least one base via is in contact with an upper surface of at least one lower via, and a width of the lower surface of the at least one base via is wider than a width of the upper surface of the at least one lower via.
Clause 25: The method of clause 24, wherein the lower surface of the at least one base via is above the lower surface of the base core.
Clause 26: The method of any of clauses 24-25, further comprising: forming one or more lower pads formed on a lower surface of the lower core and on lower surfaces of the one or more lower vias, wherein the one or more lower pads correspond to the one or more lower vias, the one or more lower pads being electrically coupled to the corresponding one or more lower vias.
Clause 27: The method of any of clauses 24-26, further comprising: forming one or more lower laminate layers stacked on and below the lower core; and forming one or more lower metal layers formed in the one or more lower laminate layers, the one or more lower metal layers distributing electrical signals to and/or from the one or more lower vias.
Clause 28: The method of any of clauses 15-27, wherein providing the core substrate and forming the one or more vias within the substrate comprises: laser drilling the base core to form one or more base via holes; plating the base core with a base conductive material to fill the one or more base via holes; etching to entirely remove the base conductive material from the upper surface of the base core, wherein top portions of the one or more base vias are also removed; providing the upper core on the upper surface of the base core; laser drilling the upper core to form one or more upper via holes exposing the upper surfaces of the one or more base vias; and plating the upper core with an upper conductive material to fill the one or more upper via holes.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or one or more claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A semiconductor package, comprising:
a core substrate comprising:
a base core; and
an upper core on an upper surface of the base core; and
one or more vias within the core substrate extending an entire height of the core substrate, the one or more vias comprising:
one or more base vias in the base core; and
one or more upper vias in the upper core, the one or more base vias corresponding to the one or more upper vias, the one or more base vias being electrically coupled to the corresponding one or more upper vias,
wherein an upper surface of at least one base via is in contact with a lower surface of at least one upper via, and a width of the upper surface of the at least one base via is wider than a width of the lower surface of the at least one upper via.

2. The semiconductor package of claim 1, wherein the upper surface of the at least one base via is below the upper surface of the base core.

3. The semiconductor package of claim 1, wherein a base via width is 70 μm or less, the base via width being a width of the one or more base vias.

4. The semiconductor package of claim 1, wherein a via pitch is 130 μm or less, the via pitch being a center-to-center distance between two adjacent vias.

5. The semiconductor package of claim 1, further comprising:
one or more upper pads formed on an upper surface of the upper core and on upper surfaces of the one or more upper vias,
wherein the one or more upper pads correspond to the one or more upper vias, the one or more upper pads being electrically coupled to the corresponding one or more upper vias.

6. The semiconductor package of claim 5, wherein an upper pad width is 105 μm or less, the upper pad width being a width of the one or more upper pads.

7. The semiconductor package of claim 1, wherein the upper core is formed from a pregreg (PPG) material, a carbon fiber (GCF) material, or both.

8. The semiconductor package of claim 1, further comprising:
one or more upper laminate layers stacked on and above the upper core; and
one or more upper metal layers formed in the one or more upper laminate layers, the one or more upper metal layers distributing electrical signals to and/or from the one or more upper vias.

9. The semiconductor package of claim 1,
wherein the core substrate further comprises a lower core on a lower surface of the base core,
wherein the one or more vias further comprises one or more lower vias in the lower core, the one or more base vias also corresponding to the one or more lower vias, the one or more base vias being electrically coupled to the corresponding one or more lower vias, and
wherein a lower surface of at least one base via is in contact with an upper surface of at least one lower via, and a width of the lower surface of the at least one base via is wider than a width of the upper surface of the at least one lower via.

10. The semiconductor package of claim 9, wherein the lower surface of the at least one base via is above the lower surface of the base core.

11. The semiconductor package of claim 9, further comprising:
one or more lower pads formed on a lower surface of the lower core and on lower surfaces of the one or more lower vias,
wherein the one or more lower pads correspond to the one or more lower vias, the one or more lower pads being electrically coupled to the corresponding one or more lower vias.

12. The semiconductor package of claim 9, further comprising:
one or more lower laminate layers stacked on and below the lower core; and
one or more lower metal layers formed in the one or more lower laminate layers, the one or more lower metal layers distributing electrical signals to and/or from the one or more lower vias.

13. The semiconductor package of claim 1, wherein the semiconductor package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

14. A method of fabricating a semiconductor package, the method comprising:
providing a core substrate comprising:
a base core; and
an upper core on an upper surface of the base core; and
forming one or more vias within the core substrate extending an entire height of the core substrate, the one or more vias comprising:
one or more base vias in the base core; and
one or more upper vias in the upper core, the one or more base vias corresponding to the one or more upper vias, the one or more base vias being electrically coupled to the corresponding one or more upper vias,
wherein an upper surface of at least one base via is in contact with a lower surface of at least one upper via, and a width of the upper surface of the at least one base via is wider than a width of the lower surface of the at least one upper via.

15. The method of claim 14, wherein the upper surface of the at least one base via is below the upper surface of the base core.

16. The method of claim 14, further comprising:
forming one or more upper pads on an upper surface of the upper core and on upper surfaces of the one or more upper vias, wherein the one or more upper pads correspond to the one or more upper vias, the one or more upper pads being electrically coupled to the corresponding one or more upper vias.

17. The method of claim 14, further comprising:
forming one or more upper laminate layers stacked on and above the upper core; and
forming one or more upper metal layers in the one or more upper laminate layers, the one or more upper metal layers distributing electrical signals to and/or from the one or more upper vias.

18. The method of claim 14,
wherein the core substrate further comprises a lower core on a lower surface of the base core,
wherein the one or more vias further comprise one or more lower vias in the lower core, the one or more base vias also corresponding to the one or more lower vias, the one or more base vias being electrically coupled to the corresponding one or more lower vias, and
wherein a lower surface of at least one base via is in contact with an upper surface of at least one lower via, and a width of the lower surface of the at least one base via is wider than a width of the upper surface of the at least one lower via.

19. The method of claim 18, wherein the lower surface of the at least one base via is above the lower surface of the base core.

20. The method of claim 14, wherein providing the core substrate and forming the one or more vias within the substrate comprises:
laser drilling the base core to form one or more base via holes;
plating the base core with a base conductive material to fill the one or more base via holes;
etching to entirely remove the base conductive material from the upper surface of the base core, wherein top portions of the one or more base vias are also removed;
providing the upper core on the upper surface of the base core;
laser drilling the upper core to form one or more upper via holes exposing the upper surfaces of the one or more base vias; and
plating by plating the upper core with an upper conductive material to fill the one or more upper via holes.
